(19) United States
(12) Patent Application Publication
(10) Pub. No.: US 2025/0095993 A1
(43) Pub. Date: Mar. 20, 2025

(54) METHOD FOR MANUFACTURING SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Seiya SAKAKURA, Hakusan Ishikawa (JP)

(21) Appl. No.: 18/584,900

(22) Filed: Feb. 22, 2024

(30) Foreign Application Priority Data
Sep. 20, 2023 (JP) 2023-151794

(51) Int. Cl. H01L 21/265; H01L 21/268; H01L 29/739; H01L 29/861

(52) U.S. Cl. CPC H01L 21/2652; H01L 21/268; H10D 8/00; H10D 12/481

(57) ABSTRACT

According to one embodiment, a method for manufacturing a semiconductor device includes a first process, a second process, and a third process. The first process is performed on a semiconductor member including a first face and a crystal. The first process includes at least one of implanting a first element into a first portion of the semiconductor member from the first face or irradiating the first portion with a particle beam. In the second process, a second element is implanted into a first region of the semiconductor member and is not implanted into a second region of the semiconductor member. The first region and the second region are located between the first face and the first portion. The third process is performed to irradiate the semiconductor member with a first electromagnetic wave from the first face through the first region and the second region, after the second process.

### CROSS-REFERENCE TO RELATED APPLICATIONS

This application is based upon and claims the benefit of priority from Japanese Patent Application No. 2023-151794, filed on Sep. 20, 2023; the entire contents of which are incorporated herein by reference.

### FIELD

Embodiments described herein generally relate to a method for manufacturing a semiconductor device.

### BACKGROUND

For example, there are semiconductor devices such as reverse conducting IGBTs (RC-IGBTs). A method for manufacturing a semiconductor device that can improve characteristics is desired.

### BRIEF DESCRIPTION OF THE DRAWINGS

FIGS. 1A to 1D are schematic cross-sectional views illustrating a method for manufacturing a semiconductor device according to a first embodiment;

FIG. 2 is a flowchart illustrating the method for manufacturing the semiconductor device according to the first embodiment; and

FIG. 3 is a schematic cross-sectional view illustrating a semiconductor device according to a second embodiment.

### DETAILED DESCRIPTION

According to one embodiment, a method for manufacturing a semiconductor device includes a first process, a second process, and a third process. The first process is performed on a semiconductor member including a first face. The semiconductor member includes a crystal. The first process includes at least one of implanting a first element into a first portion of the semiconductor member from the first face or irradiating the first portion with a particle beam. In the second process, a second element is implanted into a first region of the semiconductor member and the second element is not implanted into a second region of the semiconductor member. The first region and the second region are located between the first face and the first portion. A direction from the first region to the second region is along the first face. The third process is performed to irradiate the semiconductor member with a first electromagnetic wave from the first face through the first region and the second region, after the second process. The first electromagnetic wave has a first peak wavelength.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously in an antecedent drawing are marked with like reference numerals, and a detailed description is omitted as appropriate.

### First Embodiment

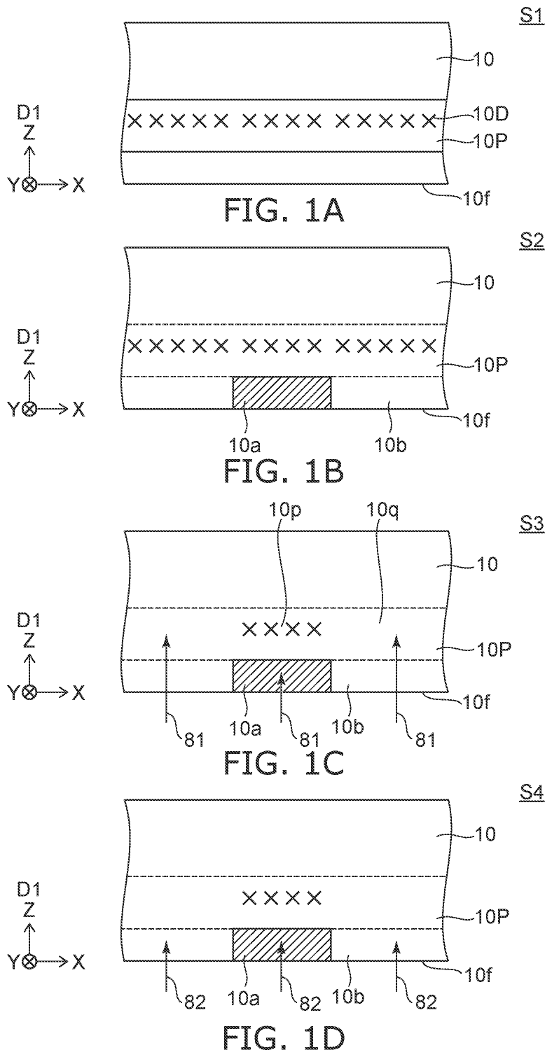

FIGS. 1A to 1D are schematic cross-sectional views illustrating a method for manufacturing a semiconductor device according to the first embodiment.

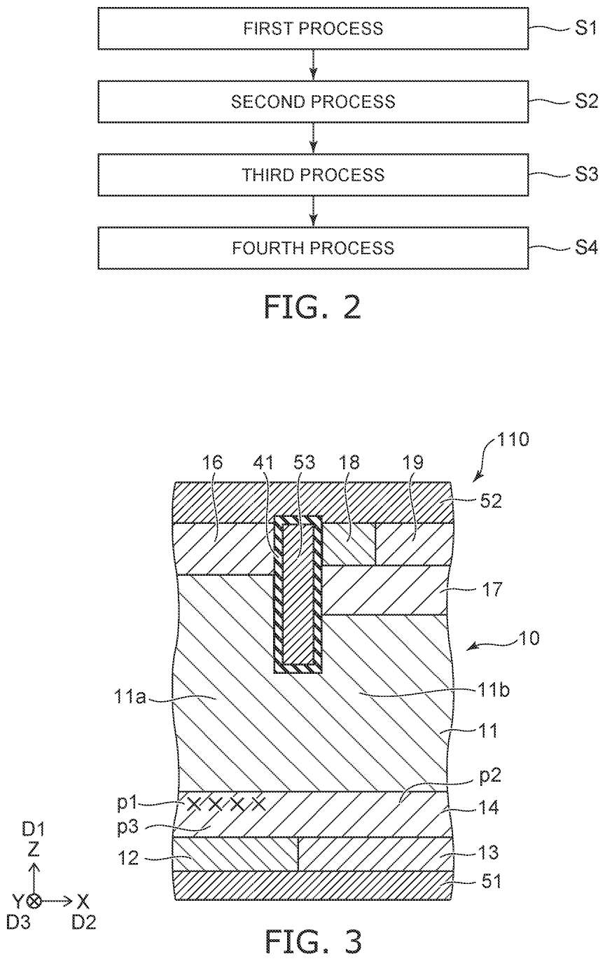

FIG. 2 is a flowchart illustrating the method for manufacturing the semiconductor device according to the first embodiment.

As shown in FIG. 2, the method for manufacturing a semiconductor device according to the embodiment includes a first process S1, a second process S2, and a third process S3. The manufacturing method may further include a fourth process S4.

As shown in FIG. 1A, the first process S1 is performed on a semiconductor member 10. The semiconductor member 10 includes a first face 10f and includes a crystal. The semiconductor member 10 includes, for example, silicon crystal. The semiconductor member 10 may include, for example, SiC crystal.

The first process S1 includes at least one of implanting a first element into a first portion 10P of the semiconductor member 10 from the first face 10f or irradiating the first portion 10P with a particle beam. For example, the first process S1 forms a defect 10D of crystal in the first portion 10P.

A direction perpendicular to the first face 10f is defined as a Z-axis direction. One direction perpendicular to the Z-axis direction is defined as an X-axis direction. A direction perpendicular to the Z-axis direction and the X-axis direction is defined as a Y-axis direction. At least a part of the first portion 10P is along the X-Y plane.

The first element includes, for example, at least one selected from the group consisting of hydrogen, helium, neon, argon, krypton, xenon, and radon. By implanting such a first element, the defect 10D is formed in the first portion 10P.

In the first process S1, the first portion 10P may be irradiated with a particle beam. The particle beam includes, for example, charged particle beam. The particle beam includes, for example, electron beams. Due to such particle beam irradiation, the defect 10D is formed in the first portion 10P.

In one example, the first element may include at least one selected from the group consisting of phosphorus, arsenic, antimony, boron, gallium, indium, and oxygen. For example, the first element may include at least one selected from the group consisting of phosphorus, arsenic, antimony, and oxygen. By such a first element, the first portion 10P may become an n-type semiconductor region. For example, the first element may include at least one selected from the group consisting of boron, gallium, and indium. By such a first element, the first portion 10P may become a p-type semiconductor region. For example, the defect 10D may be formed by the first element that provides the conductivity type.

As shown in FIG. 1B, in the second process S2, a second element is implanted into a first region 10a of the semiconductor member 10. The second element is not implanted into a second region 10b of the semiconductor member 10. Thus, in the second process S2, the second element is selectively implanted into the first region 10a. Examples of the second element will be described later.

As shown in FIG. 1B, the first region 10a and the second region 10b are located between the first face 10f and the first portion 10P. A direction from the first region 10a to the second region 10b is along the first face 10f.

The first region 10a may have an island shape or a stripe shape. The planar shape of the first region 10a is arbitrary.

The third process S3 is performed after the second process S2. As shown in FIG. 1C, in the third process S3, the first electromagnetic wave 81 is irradiated from the first face 10f to the semiconductor member 10 via the first region 10a and the second region 10b. The first electromagnetic wave 81 has, for example, a first peak wavelength.

The first portion 10P includes an overlapping portion 10p that overlaps the first region 10a and a non-overlapping portion 10q that does not overlap the first region 10a in the Z-axis direction (first direction D1). The non-overlapping portion 10q overlaps the second region 10b in the first direction D1. The first electromagnetic wave 81 passes through the second region 10b and reaches the non-overlapping portion 10q. By irradiating the first electromagnetic wave 81, the defect 10D included in the non-overlapping portion 10q is recovered. On the other hand, the first electromagnetic wave 81 is attenuated in the first region 10a. Therefore, the degree of recovery of the defect 10D included in the overlapping portion 10p is low. The defect 10D remains in the overlapping portion 10p.

In this way, in the embodiment, crystal defects 10D can be efficiently and selectively formed. For example, the defect 10D can function as a trap for carriers flowing through the semiconductor member 10. For example, the lifetime of the carrier can be controlled by the defect 10D. By locally forming the defect 10D in the semiconductor member 10, it is possible to effectively suppress carriers injected during operation of the semiconductor device from flowing through the semiconductor member 10. According to the embodiment, it is possible to provide a method for manufacturing a semiconductor device whose characteristics can be improved.

By applying the method for manufacturing the semiconductor device according to the embodiment, the characteristics of, for example, an RC-IGBT (Reverse Conducting Insulated Gate Bipolar Transistor) can be effectively improved. For example, turn-off loss can be effectively suppressed in RC-IGBT.

As described above, in the embodiment, the first process S1 includes forming a crystal defect (defect 10D) in the first portion 10P.

At least a part of the first electromagnetic wave 81 irradiated in the third process S3 is absorbed in the first region 10a. In the second process S2, such a first region 10a is formed. That is, the second process S2 causes the first absorptance of the first region 10a for electromagnetic waves having the first peak wavelength to be higher than the second absorptance of the second region 10b for electromagnetic waves having the first peak wavelength.

As already explained, in the second process S2, the second element is implanted into the first region 10a. This reduces the crystallinity in the first region 10a. For example, the crystallinity in the first region 10a after the second process S2 is lower than the crystallinity in the second region 10b after the second process S2.

For example, before the second process S2, the first region 10a and the second region 10b include crystals. After the second process S2, at least a portion of the first region 10a may include an amorphous region. In the first region 10a with low crystallinity, the first electromagnetic wave 81 having the first peak wavelength is effectively absorbed. This effectively leaves the defect 10D in the overlapping portion 10p overlapping the first region 10a.

For example, the second element implanted in the second process S2 may include at least one selected from the group consisting of phosphorus, arsenic, antimony, silicon, germanium, carbon, nitrogen, oxygen, and argon. Thereby, the crystallinity in the first region 10a into which the second element is implanted is effectively reduced. For example, the second process S2 may include a first implantation and a second implantation. In the first implantation, for example, at least one element selected from the group consisting of silicon, germanium, carbon, nitrogen, oxygen, and argon is implanted. In the second implantation, for example, at least one element selected from the group consisting of phosphorus, arsenic, and antimony is implanted. The second implantation may be performed after the first implantation. The first implantation may be performed after the second implantation. For example, irradiation with electromagnetic waves (e.g., infrared laser, etc.) may be performed between the first implantation and the second implantation. Activation may be performed by irradiation with this electromagnetic wave.

The first region 10a into which the second element is implanted in the second process S2 may have the conductivity given by the second element. The crystallinity in the first region 10a, which has decreased due to the implantation of the second element, may be recovered by the fourth process S4 (see FIG. 2).

The fourth process S4 is performed after the third process S3. As shown in FIG. 1D, in the fourth process S4, the second electromagnetic wave 82 is irradiated onto the first region 10a. By irradiating the first region 10a with the second electromagnetic wave 82, for example, the crystallinity in the first region 10a is recovered. The second electromagnetic wave 82 has a second peak wavelength. In one example, the second peak wavelength is shorter than the first peak wavelength. By irradiating the first region 10a with such second electromagnetic waves 82, the crystallinity in the first region 10a is more effectively recovered.

For example, the first electromagnetic wave 81 is infrared rays. The second electromagnetic wave 82 is ultraviolet light or visible light. For example, the first peak wavelength is not less than 690 nm and not more than 3000. For example, the second peak wavelength is not less than 100 nm and not more than 690 nm. In one example, the first peak wavelength is 808 nm. In one example, the second peak wavelength is 527 nm. For example, the peak wavelength of the first electromagnetic wave 81 may be not less than 100 nm and not more than 3000 nm. For example, the peak wavelength of the second electromagnetic wave 82 may be not more than 100 nm and not more than 830 nm.

In one example, the first electromagnetic wave 81 is an infrared laser. The second electromagnetic wave 82 is a green laser. For example, the first electromagnetic wave 81 may include a pulsed laser having a first pulse width not less than 1 us and not more than 200 us. For example, the second electromagnetic wave 82 may include a pulsed laser having a second pulse width of not less than 50 ns and not more than 1200 ns.

For example, the irradiation of the second electromagnetic wave 82 to the first region 10a may melt at least a part of the first region 10a. This effectively recovers the defect 10D in the first region 10a. On the other hand, the irradiation of the first electromagnetic wave 81 to the first region 10a does not need to melt the first region 10a.

As shown in FIG. 1D, the irradiation of the second electromagnetic wave 82 may include irradiating the second region 10b with the second electromagnetic wave 82. The crystallinity in the second region 10b is improved. Irradiation is carried out in a simple process.

In this way, the fourth process S4 increases the crystallinity in the first region 10a, for example. Good conductivity can be obtained. The crystallinity in the first region 10a after the fourth process S4 is higher than the crystallinity in the first region 10a after the third process S3 and before the fourth process S4.

When the first process S1 includes the implantation of the first element, a first dose amount of the first element in the implantation of the first element may be lower than a second dose amount of the second element to the first region 10a in the second process S2. The defects 10D being intended can be effectively formed by the implantation of the first element at a low dose. The dose amount of the first element in the implantation of the first element may be, for example, not less than 1×10¹² cm⁻² and not more than 5×10¹³ cm⁻² (e.g., about 2×10¹² cm⁻²).

On the other hand, by implanting the second element at a sufficiently high dose, the absorption rate at the first peak wavelength in the first region 10a effectively increases. For example, after the second process S2, at least a part of the first region 10a includes an amorphous region.

In one example, the second dose amount of the second element to the first region 10a in the second process S2 is 5×10¹⁴ cm⁻² or more. The second dose amount may be, for example, 1×10¹⁶ cm⁻² or less. The second dose amount may be, for example, 5×10¹⁶ cm⁻² or less.

For example, in a first sample in which the first process S1 and the third process S3 were performed without performing the second process S2, the carrier activation rate in the overlapping portion 10p was 73%. On the other hand, in a second sample subjected to the first process S1, the second process S2 (second dose amount is 1×10¹⁵ cm⁻²), and the third process S3, the carrier activation rate in the overlapping portion 10p is 0.5%. In a third sample subjected to the first process S1, the second process S2 (second dose amount is 3×10¹⁵ cm⁻²), and the third process S3, the carrier activation rate in the overlapping portion 10p is 0.2%. Thus, by performing the second process S2, the first electromagnetic wave 81 in the third process S3 is effectively attenuated in the first region 10a, and the defect 10D remains effectively in the overlapping portion 10p.

At least when the second dose is 5×10¹⁴ cm⁻² or more, the defect 10D can be effectively left.

### Second Embodiment

The second embodiment relates to a semiconductor device to which method for manufacturing the semiconductor device of the first embodiment can be applied.

FIG. 3 is a schematic cross-sectional view illustrating a semiconductor device according to the second embodiment.

As shown in FIG. 3, a semiconductor device 110 according to the second embodiment includes a first electrode 51 and a semiconductor member 10.

The semiconductor member 10 includes a first semiconductor region 11, a second semiconductor region 12, a third semiconductor region 13, and a fourth semiconductor region 14. The first semiconductor region 11 is of a first conductivity type. The second semiconductor region 12 is provided between the first electrode 51 and the first semiconductor region 11. The second semiconductor region 12 is of the first conductivity type.

The third semiconductor region 13 is provided between the first electrode 51 and the first semiconductor region 11, and is of a second conductivity type. A second direction D2 from the second semiconductor region 12 to the third semiconductor region 13 crosses the first direction D1 from the first electrode 51 to the semiconductor member 10. The first conductivity type is one of n-type and p-type. The second conductivity type is the other of n-type and p-type. In the following, the first conductivity type is n-type, and the second conductivity type is p-type.

The fourth semiconductor region 14 is of the first conductivity type. The fourth semiconductor region 14 is located between the second semiconductor region 12 and the first semiconductor region 11 and between the third semiconductor region 13 and the first semiconductor region 11.

The semiconductor member 10 includes a first partial region p1 and a second partial region p2. The first partial region p1 overlaps the second semiconductor region 12 in the first direction D1. The second partial region p2 overlaps the third semiconductor region 13 in the first direction D1. A carrier concentration in the first partial region p1 is lower than a carrier concentration in the second partial region p2.

In the semiconductor device 110, the second semiconductor region 12 corresponds to the first region 10a. The third semiconductor region 13 may correspond to the second region 10b. By irradiating the first electromagnetic wave 81 through the second semiconductor region 12, the first electromagnetic wave 81 is attenuated, and the carrier concentration is maintained low in the first partial region p1. On the other hand, a high carrier density is obtained in the second partial region p2 that does not overlap the second semiconductor region 12. For example, the high carrier density in the second partial region p2 is considered to be due to recovery of the defect 10D of crystal caused by the first electromagnetic wave 81, for example.

As shown in FIG. 3, the semiconductor member 10 may further include a third partial region p3. The third partial region p3 is provided between the second semiconductor region 12 and the first partial region p1 in the first direction D1. A carrier concentration in the third partial region p3 may be higher than the carrier concentration in the first partial region p1.

In the semiconductor device 110, the carrier concentration in the second semiconductor region 12 may be higher than the carrier concentration in the first partial region p1. The carrier concentration in the second semiconductor region 12 is higher than the carrier concentration in the first semiconductor region 11.

As shown in FIG. 3, the semiconductor device 110 may further include a second electrode 52, a third electrode 53, and a first insulating member 41. The semiconductor member 10 is provided between the first electrode 51 and the second electrode 52 in the first direction D1. The first semiconductor region 11 includes a first semiconductor portion 11a and a second semiconductor portion 11b. The first semiconductor portion 11a is provided between the second semiconductor region 12 and the second electrode 52 in the first direction D1. The second semiconductor portion 11b is provided between the third semiconductor region 13 and the second electrode 52 in the first direction D1.

The semiconductor member 10 may further include a sixth semiconductor region 16 of the second conductivity type, a seventh semiconductor region 17 of the second conductivity type, and an eighth semiconductor region 18 of the first conductivity type. The sixth semiconductor region 16 is provided between the first semiconductor portion 11a and the second electrode 52 in the first direction D1. The eighth semiconductor region 18 is provided between the second semiconductor portion 11b and the second electrode 52 in the first direction D1. At least a part of the seventh semiconductor region 17 is provided between the eighth semiconductor region 18 and the second semiconductor portion 11b in the first direction D1.

The second electrode 52 is electrically connected to the sixth semiconductor region 16 and the eighth semiconductor region 18. The third electrode 53 faces the first semiconductor region 11, the seventh semiconductor region 17, and the eighth semiconductor region 18. At least a part of the first insulating member 41 is provided between the third electrode 53 and the semiconductor member 10. The first insulating member 41 electrically insulates the third electrode 53 and the semiconductor member 10.

The current flowing between the first electrode 51 and the second electrode 52 can be controlled by a potential of the third electrode 53. The second semiconductor region 12 is included in an FRD (Fast Recovery Diode). The third semiconductor region 13 is included in an IGBT (Insulated Gate Bipolar Transistor). The semiconductor device 110 is, for example, an RC-IGBT.

As shown in FIG. 3, the semiconductor member 10 may further include a ninth semiconductor region 19 of the second conductivity type. The ninth semiconductor region 19 is provided between the seventh semiconductor region 17 and the second electrode 52 in the first direction D1. The eighth semiconductor region 18 is provided between the third electrode 53 and the ninth semiconductor region 19. The impurity concentration of the second conductivity type in the ninth semiconductor region 19 is higher than the impurity concentration of the second conductivity type in the seventh semiconductor region 17. The second electrode 52 is electrically connected to the ninth semiconductor region 19.

In the embodiment, information regarding the defect 10D may be obtained by evaluating carrier density, for example. Information regarding the defect 10D may be obtained, for example, by electron microscopy r or X-ray diffraction. Information regarding crystallinity may be obtained, for example, by electron microscopy or X-ray diffraction. Information regarding length and thickness can be obtained by electron microscopy or the like. Information regarding the presence or absence and concentration of elements can be obtained by SIMS (Secondary Ion Mass Spectrometry), EDX (Energy dispersive X-ray spectroscopy), or the like.

The embodiments may include the following Technical proposals:

### (Technical Proposal 1)

A method for manufacturing a semiconductor device, the method comprising:
a first process performed on a semiconductor member including a first face, the semiconductor member including a crystal, the first process including at least one of implanting a first element into a first portion of the semiconductor member from the first face or irradiating the first portion with a particle beam;
a second process to implant a second element into a first region of the semiconductor member and not to implant the second element into a second region of the semiconductor member, the first region and the second region being located between the first face and the first portion, a direction from the first region to the second region being along the first face; and
a third process to irradiate the semiconductor member with a first electromagnetic wave from the first face through the first region and the second region after the second process, the first electromagnetic wave having a first peak wavelength.

### (Technical Proposal 2)

The method for manufacturing the semiconductor device according to Technical proposal 1, wherein
the first process includes forming a defect of crystal in the first portion.

### (Technical Proposal 3)

The method for manufacturing the semiconductor device according to Technical proposal 1 or 2, wherein
the second processing causes a first absorptance of the first region with respect to the electromagnetic wave having the first peak wavelength to be higher than a second absorptance of the second region with respect to the electromagnetic wave having the first peak wavelength.

### (Technical Proposal 4)

The method for manufacturing the semiconductor device according to any one of Technical proposals 1-3, wherein
the first element includes at least one selected from the group consisting of hydrogen, helium, neon, argon, krypton, xenon, and radon, and
the particle beam includes an electron beam.

### (Technical Proposal 5)

The method for manufacturing the semiconductor device according to any one of Technical proposals 1-3, wherein
the semiconductor member includes silicon, and
the first element includes at least one selected from the group consisting of phosphorus, arsenic, and antimony.

### (Technical Proposal 6)

The method for manufacturing the semiconductor device according to any one of Technical proposals 1-5, wherein
the second element includes at least one selected from the group consisting of phosphorus, arsenic, antimony, silicon, germanium, carbon, nitrogen, oxygen, and argon.

### (Technical Proposal 7)

The method for manufacturing the semiconductor device according to any one of Technical proposals 1-6, further comprising:
a fourth process performed after the third process,
the fourth process including irradiating the first region with a second electromagnetic wave.

### (Technical Proposal 8)

The method for manufacturing the semiconductor device according to Technical proposal 7, wherein
the irradiating the second electromagnetic wave includes irradiating the second region with the second electromagnetic wave.

### (Technical Proposal 9)

The method for manufacturing the semiconductor device according to Technical proposal 7 or 8, wherein
the second electromagnetic wave has a second peak wavelength, and
the second peak wavelength is shorter than the first peak wavelength.

### (Technical Proposal 10)

The method for manufacturing the semiconductor device according to Technical proposal 9, wherein
the first electromagnetic wave is infrared ray, and
the second electromagnetic wave is ultraviolet light or visible light.

### (Technical Proposal 11)

The method for manufacturing the semiconductor device according to any one of Technical proposals 7-10, wherein
the fourth process increases a crystallinity in the first region.

### (Technical Proposal 12)

The method for manufacturing the semiconductor device according to any one of Technical proposals 7-10, wherein
a crystallinity in the first region after the fourth process is higher than a crystallinity in the first region after the third process and before the fourth process.

### (Technical Proposal 13)

The method for manufacturing the semiconductor device according to any one of Technical proposals 7-11, wherein
the irradiating the first region with the second electromagnetic wave melts at least a part of the first region.

### (Technical Proposal 14)

The method for manufacturing the semiconductor device according to Technical proposal 13, wherein
the irradiating the first region with the first electromagnetic wave does not melt the first region.

### (Technical Proposal 15)

The method for manufacturing the semiconductor device according to Technical proposal 3, wherein
a second dose amount of the second element to the first region in the second process is 5×10¹⁴ cm⁻² or more.

### (Technical Proposal 16)

The method for manufacturing the semiconductor device according to Technical proposal 3, wherein
a second dose amount of the second element to the first region in the second process is not less than 5×10¹⁴ cm⁻² and not more than 5×10¹⁶ cm⁻².

### (Technical Proposal 17)

The method for manufacturing the semiconductor device according to any one of Technical proposals 1-13, wherein
the first process includes the implanting the first element, and
a dose amount of the first element in the implanting the first element is lower than a second dose amount of the second element to the first region in the second process.

### (Technical Proposal 18)

The method for manufacturing the semiconductor device according to any one of Technical proposals 7-14, wherein
the second electromagnetic wave includes a pulse laser having a second pulse width of not less than 50 ns and not more than 1200 ns.

### (Technical Proposal 19)

The method for manufacturing the semiconductor device according to any one of Technical proposals 1-18, wherein
the first electromagnetic wave includes a pulse laser having a first pulse width of not less than 1 us and not more than 200 μs.

### (Technical Proposal 20)

The method for manufacturing the semiconductor device according to any one of Technical proposals 1-19, wherein
after the second process, at least a part of the first region includes an amorphous region.

According to the embodiment, a method for manufacturing a semiconductor device that can improve characteristics can be provided.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor devices such as electrodes, semiconductor members, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all methods for manufacturing semiconductor devices practicable by an appropriate design modification by one skilled in the art based on the methods for manufacturing semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A method for manufacturing a semiconductor device, the method comprising:
a first process performed on a semiconductor member including a first face, the semiconductor member including a crystal, the first process including at least one of implanting a first element into a first portion of the semiconductor member from the first face or irradiating the first portion with a particle beam;
a second process to implant a second element into a first region of the semiconductor member and not to implant the second element into a second region of the semiconductor member, the first region and the second region being located between the first face and the first portion, a direction from the first region to the second region being along the first face; and
a third process to irradiate the semiconductor member with a first electromagnetic wave from the first face through the first region and the second region after the second process, the first electromagnetic wave having a first peak wavelength.

2. The method according to claim 1, wherein
the first process includes forming a defect of crystal in the first portion.

3. The method according to claim 1, wherein
the second processing causes a first absorptance of the first region with respect to the electromagnetic wave having the first peak wavelength to be higher than a second absorptance of the second region with respect to the electromagnetic wave having the first peak wavelength.

4. The method according to claim 1, wherein
the first element includes at least one selected from the group consisting of hydrogen, helium, neon, argon, krypton, xenon, and radon, and
the particle beam includes an electron beam.

5. The method according to claim 1, wherein
the semiconductor member includes silicon, and
the first element includes at least one selected from the group consisting of phosphorus, arsenic, and antimony.

6. The method according to claim 1, wherein
the second element includes at least one selected from the group consisting of phosphorus, arsenic, antimony, silicon, germanium, carbon, nitrogen, oxygen, and argon.

7. The method according to claim 1, further comprising:
a fourth process performed after the third process,
the fourth process including irradiating the first region with a second electromagnetic wave.

8. The method according to claim 7, wherein
the irradiating the second electromagnetic wave includes irradiating the second region with the second electromagnetic wave.

9. The method according to claim 7, wherein
the second electromagnetic wave has a second peak wavelength, and
the second peak wavelength is shorter than the first peak wavelength.

10. The method according to claim 9, wherein
the first electromagnetic wave is infrared ray, and
the second electromagnetic wave is ultraviolet light or visible light.

11. The method according to claim 7, wherein
the fourth process increases a crystallinity in the first region.

12. The method according to claim 7, wherein
a crystallinity in the first region after the fourth process is higher than a crystallinity in the first region after the third process and before the fourth process.

13. The method according to claim 7, wherein
the irradiating the first region with the second electromagnetic wave melts at least a part of the first region.

14. The method according to claim 13, wherein
the irradiating the first region with the first electromagnetic wave does not melt the first region.

15. The method according to claim 3, wherein
a second dose amount of the second element to the first region in the second process is 5×10¹⁴ cm⁻² or more.

16. The method according to claim 3, wherein
a second dose amount of the second element to the first region in the second process is not less than 5×10¹⁴ cm⁻² and not more than 5×10¹⁶ cm⁻².

17. The method according to claim 1, wherein
the first process includes the implanting the first element, and
a dose amount of the first element in the implanting the first element is lower than a second dose amount of the second element to the first region in the second process.

18. The method according to claim 7, wherein
the second electromagnetic wave includes a pulse laser having a second pulse width of not less than 50 ns and not more than 1200 ns.

19. The method according to claim 1, wherein
the first electromagnetic wave includes a pulse laser having a first pulse width of not less than 1 μs and not more than 200 μs.

20. The method according to claim 1, wherein
after the second process, at least a part of the first region includes an amorphous region.
